(19) United States
(12) Patent Application Publication
(10) Pub. No.: US 2025/0216463 A1
(43) Pub. Date: Jul. 3, 2025

(54) BATTERY QUALITY DETECTION METHOD

(71) Applicants: Jih-Hsing LEE, Taoyuan City (TW); Chia-Li LIN, Taoyuan City (TW); Hui-Shan LIU, Taoyuan City (TW)

(72) Inventors: Jih-Hsing LEE, Taoyuan City (TW); Chia-Li LIN, Taoyuan City (TW); Hui-Shan LIU, Taoyuan City (TW)

(21) Appl. No.: 18/991,782

(22) Filed: Dec. 23, 2024

(30) Foreign Application Priority Data
Dec. 28, 2023 (TW) 112151182

(51) Int. Cl. G01R 31/367; G01R 31/3842

(52) U.S. Cl. CPC G01R 31/367; G01R 31/3842

(57) ABSTRACT

The present invention provides a battery quality detection method, comprising the following steps: selecting a plurality of test data with a data concentration greater than a first threshold; determining an upper limit curve and a lower limit curve for the selected test data; setting a standard detection range between the upper limit curve and the lower limit curve; obtaining a battery characteristic waveform of a battery; and comparing the battery characteristic waveform with the standard detection range to evaluate the battery's quality.

### BACKGROUND OF THE INVENTION

### Cross Reference to Related Application

The present application claims priority to Taiwan patent application Serial No. 112151182 filed on Dec. 28, 2023 the entire content of which is incorporated by reference to this application.

### 1. FIELD OF THE INVENTION

The present invention relates to a battery quality detection method, particularly to a method for evaluating battery quality by detecting battery charge and discharge curves.

### 2. DESCRIPTION OF THE PRIOR ART

To assess battery quality, industry professionals typically subject batteries to a series of charge and discharge tests and analyze the voltage and current values during these processes. For instance, in a battery charging test, the charging process often involves switching between different charging modes. For example, when the battery voltage is below its rated voltage, a constant current (CC) mode may be used for charging, whereas when the battery voltage approaches the rated voltage, a constant voltage (CV) mode may be adopted instead. Additionally, as the battery reaches its maximum capacity, the charging current gradually decreases. Those skilled in the art will understand that the voltage and current of a battery often exhibit varying degrees of change at different time points.

To determine whether a battery's charge-discharge behavior meets expectations, a conventional approach involves setting a fixed upper limit for voltage (or current) and checking whether the battery's voltage (or current) deviates from this limit to detect anomalies. For example, if a battery is charged at a constant voltage or a known maximum charging voltage of 4.2V, the upper voltage limit is typically set at 4.5V. If the battery voltage deviates from 4.5V during charging, the charge-discharge behavior is deemed abnormal. However, such a fixed voltage upper limit is typically only suitable for situations where the voltage is relatively stable and close to the rated voltage. It is understandable that when the battery voltage is far from the rated voltage, relying solely on an upper voltage limit as the criterion for detecting anomalies can be insufficient. In practice, when the battery voltage is significantly below the rated voltage, changes in voltage (or current) tend to be rapid, causing the rate of the voltage (or current) increase to vary greatly under different charging current conditions. Consequently, it is often challenging to set precise conditions to accurately detect abnormalities in battery charge-discharge behavior.

Accordingly, the industry requires a new battery detection method capable of adapting to various testing scenarios to enhance the accuracy of battery quality analysis.

### SUMMARY OF THE INVENTION

The present invention provides a battery quality detection method adaptable to various battery testing scenarios, thereby improving the accuracy of battery quality analysis.

The invention proposes a battery quality detection method, comprising the following steps: selecting a plurality of test data with a data concentration greater than a first threshold; determining an upper limit curve and a lower limit curve for the selected test data; setting a standard detection range between the upper limit curve and the lower limit curve; obtaining a battery characteristic waveform of a battery; and comparing the battery characteristic waveform with the standard detection range to evaluate the battery's quality.

In some embodiments, the step of determining the upper limit curve and the lower limit curve for the selected test data via an image processing procedure further comprises: obtaining an upper contour line and a lower contour line for the selected test data via the image processing procedure; and generating the upper limit curve and the lower limit curve based on the upper contour line and the lower contour line, respectively.

In some embodiments, the step of determining the upper limit curve and the lower limit curve for the selected test data via an image processing procedure further comprises: generating a standard curve based on the selected test data; and generating the upper limit curve and the lower limit curve via the image processing procedure based on the standard curve. The image processing procedure may at least involve stretching or compressing the standard curve to obtain the upper limit curve and the lower limit curve. Furthermore, in the step of generating the upper limit curve and the lower limit curve based on the standard curve via the image processing procedure, the method may further include: when a deviation of the selected test data within a time interval is less than a second threshold, shifting the standard curve within the time interval via the image processing procedure to obtain the upper limit curve and the lower limit curve within the time interval; and when the deviation of the selected test data within the time interval is not less than the second threshold, stretching or compressing the standard curve within the time interval via the image processing procedure to obtain the upper limit curve and the lower limit curve within the time interval.

In some embodiments, the separation between the upper limit curve and the lower limit curve forms an range width of the standard detection range, and the value of the range width within a time interval is at least associated with a standard deviation of the selected test data for that time interval. Here, the standard curve may be a median value curve or an average curve of the selected test data. Additionally, when the difference between the standard curve and a preset curve deviates from a third threshold, the standard curve is judged as abnormal.

In some embodiments, the step of comparing the battery characteristic waveform with the standard detection range to evaluate the battery's quality further comprises: using an image processing procedure to determine whether the battery characteristic waveform deviates from the standard detection range to evaluate the battery's quality.

The invention also proposes a battery quality detection method, comprising the following steps: calculating values for a standard curve within a first time interval from a plurality of test data; calculating a standard deviation of the plurality of test data within the first time interval; determining values for an upper limit curve and a lower limit curve within the first time interval based on the values for the standard curve and the standard deviation; setting a standard detection range between the values of the upper limit curve and the lower limit curve within the first time interval; and comparing a battery characteristic waveform of a battery within the first time interval with the standard detection range to evaluate the battery's quality.

In some embodiments, the standard curve is related to an average value or a median value of the plurality of test data within the first time interval. When the battery characteristic waveform within the first time interval deviates from the standard detection range, the battery is judged as abnormal.

In summary, unlike traditional battery quality detection methods that are prone to misjudgments when battery voltage changes abruptly and may become overly lenient when voltage stabilizes after increasing tolerance limits, the battery quality detection method of the present invention dynamically adjusts the standard detection range using an image processing procedure. This approach maintains strict quality control when the battery voltage is stable while providing a larger standard detection range during abrupt voltage changes to reduce misjudgments, thereby enhancing the accuracy of battery quality analysis.

### BRIEF DESCRIPTION OF THE APPTERMINALED DRAWINGS

FIG. 1 is a schematic diagram illustrating a method for detecting voltage values.

FIG. 2 is a schematic diagram illustrating another method for detecting voltage values.

FIG. 3 is a schematic diagram illustrating a plurality of test data according to an embodiment of the present invention.

FIG. 4 is a schematic diagram illustrating filtered test data according to an embodiment of the present invention.

FIG. 5 is a schematic diagram illustrating an upper limit curve and a lower limit curve according to an embodiment of the present invention.

FIG. 6 is a schematic diagram illustrating a standard curve according to an embodiment of the present invention.

FIG. 7 is a schematic diagram illustrating a standard curve, an upper limit curve, and a lower limit curve according to an embodiment of the present invention.

FIG. 8 is a flowchart illustrating the steps of a battery quality detection method according to an embodiment of the present invention.

FIG. 9 is a flowchart illustrating the steps of a battery quality detection method according to another embodiment of the present invention.

### DETAILED DESCRIPTION OF THE INVENTION

The features, targetions, and functions of the present invention are further disclosed below. However, it is only a few of the possible embodiments of the present invention, and the scope of the present invention is not limited thereto; that is, the equivalent changes and modifications done in accordance with the claims of the present invention will remain the subject of the present invention. Without departing from the spirit and scope of the invention, it should be considered as further enablement of the invention.

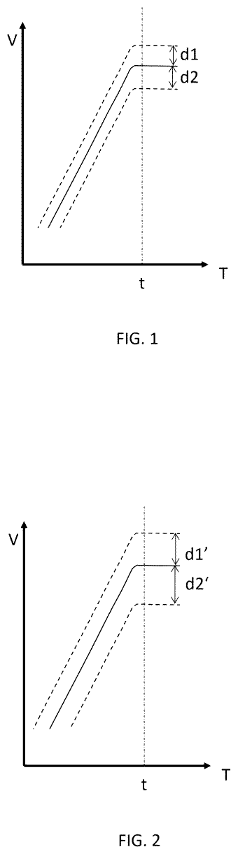

To illustrate the advantages of the battery quality detection method of the present invention, please refer to FIG. 1, which is a schematic diagram illustrating a method for detecting voltage values. In addition to the aforementioned approach where a user might set only a fixed upper limit as a detection standard, users can also attempt to define a detection range to improve the accuracy of anomaly detection. As shown in FIG. 1, in one battery quality detection method, a user can determine the battery's charging and discharging characteristics based on its specifications, such as the battery voltage values under a specific test procedure (recipe). Here, the user can plot the corresponding battery voltage values from the specifications as a solid-line curve in FIG. 1 based on the recipe to be tested. Furthermore, due to manufacturing or measurement errors, the user may shift the solid-line curve upward by a certain distance (tolerance threshold d1) and downward by a certain distance (tolerance threshold d2), forming two dashed lines above and below the solid-line curve in FIG. 1. Generally, as long as the battery's voltage values during formal measurement fall within the detection range defined by these two dashed lines, the battery is deemed normal after testing.

However, when testing a battery's charging characteristics, the charging mode or charging current may change depending on the recipe being tested, causing significant voltage deviations during mode transitions. For example, when the battery voltage is far below a preset value, a larger charging current results in a rapid voltage rise, leading to a steep waveform slope when plotted as voltage values. When the battery nears its rated voltage and switches to constant voltage charging, the slope of the voltage waveform plotted from voltage values becomes minimal. This example illustrates that the waveform slope frequently changes. At this point, simply shifting the solid-line curve (fixed tolerance thresholds d1, d2) poses little issue after time t, as the battery voltage values are relatively stable. However, before time t, those skilled in the art will recognize that the battery voltage is changing rapidly and is highly susceptible to various measurement errors. Yet, the error tolerance level of the detection range before time t is very low, often leading to a significant number of batteries being flagged as abnormal at this stage, even though they may not actually be defective.

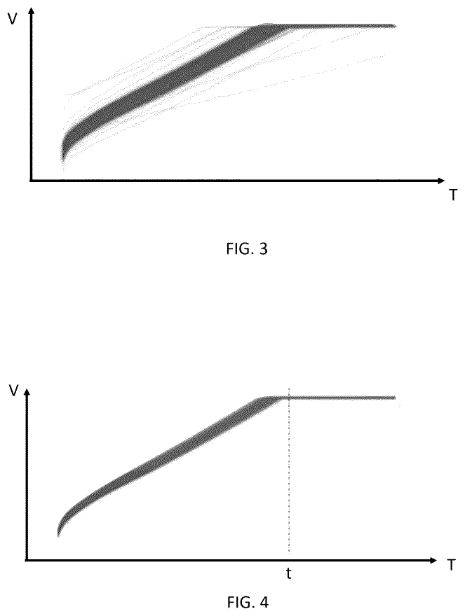

To address this issue, users might adjust the tolerance thresholds d1 and d2 to reduce the false positive rate detections during phases of rapid voltage changes. Please refer to FIGS. 1 and 2 together, where FIG. 2 is a schematic diagram illustrating another method for detecting voltage values. As shown, FIG. 2 expands the detection range to reduce false anomaly rates, such as by setting tolerance thresholds d1′ and d2′ to be greater than the original d1 and d2, respectively. Those skilled in the art will understand that the widened tolerance thresholds d1′ and d2′ provide greater error tolerance before time t but introduce another problem: reduced detection precision after time t, potentially misclassifying abnormal battery voltage values as normal. Accordingly, the present invention proposes the following battery quality detection method.

The battery quality detection method of the present invention is applied to battery charge-discharge testing by measuring the voltage and current of a battery at each time point during the test and using these measured data to assess the battery's quality. Please refer to FIG. 3, which is a schematic diagram illustrating a plurality of test data according to an embodiment of the present invention. This embodiment demonstrates voltage data (test data) from numerous batteries during a charging test, with each measured test datum plotted as a curve. Each curve in FIG. 3 represents the voltage values of a battery measured at different time points. In this embodiment, a computer is used to generate corresponding curves for each test datum, overlaying them on the same display interface to produce the content shown in FIG. 3.

This embodiment does not limit the method of generating the test data. For example, the test data could be results generated through repeated program simulations or obtained from actual repeated testing of a small number of batteries. Alternatively, the test data might consist of battery test results from previous tests using the same test procedure (recipe), i.e., recorded voltage values from one or more prior batches of batteries. Additionally, the test data could be obtained from repeated laboratory testing of a standard component (standard battery).

Next, since some curves in FIG. 3 may exhibit significant deviation—such as when using a previously obtained batch of test data that includes curves from abnormal batteries—this embodiment may further filter the curves in FIG. 3. Please refer to FIG. 4, which is a schematic diagram illustrating filtered test data according to an embodiment of the present invention. In practice, this embodiment can select a plurality of test data with a data concentration greater than a first threshold. Moreover, this embodiment can adjust the data concentration threshold based on the source of the test data. For instance, if a previously obtained batch of test data is used, as mentioned earlier, and it is expected to include abnormal cases, test data with a data concentration greater than 30% (first threshold) might be selected to exclude significantly deviated test data. On the other hand, if the test data is derived from program simulations or standard components and is expected to be more accurate, the data concentration criterion can be relaxed to utilize more test data.

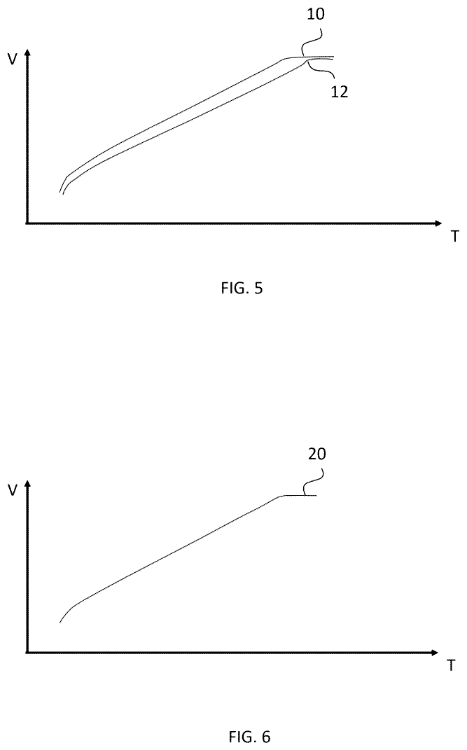

After filtering the test data, this embodiment may use image processing to obtain the standard detection range. Please refer to FIG. 5, which is a schematic diagram illustrating an upper limit curve and a lower limit curve according to an embodiment of the present invention. As shown in FIG. 5, applying image processing to FIG. 4 allows the identification of the upper contour line and lower contour line of the entire pattern in FIG. 4, and the standard detection range is determined based on these contour lines. In practice, users may choose to directly use the upper contour line and lower contour line as the upper limit curve 10 and the lower limit curve 12 of the standard detection range, or they may adjust the upper and lower contour lines via image processing to obtain the upper limit curve 10 and the lower limit curve 12. This embodiment imposes no restrictions in this regard.

For actual testing, after obtaining the test data of a battery under evaluation, the test data can be plotted as a curve (i.e., the battery characteristic waveform) and compared with the standard detection range. If the battery characteristic waveform of the battery under test deviates from the upper limit curve or the lower limit curve (i.e., falls outside the standard detection range), the battery can be deemed abnormal. Conversely, if the battery characteristic waveform remains between the upper limit curve and the lower limit curve, the battery can be considered free of anomalies. In one example, an image processing procedure can be used to automatically compare whether the battery characteristic waveform of the battery under test deviates from the standard detection range when detecting anomalies, though this embodiment imposes no restrictions. Additionally, there may be numerous methods for evaluating whether a battery under test is normal, and this embodiment's determination of whether the battery characteristic waveform deviates from the standard detection range is merely one exemplary evaluation criterion, with other methods omitted here for brevity.

Notably, as observed in FIG. 4, before the battery is fully charged (time t), the data concentration of the test data varies significantly due to various factors. After the battery is fully charged (time t), the test data becomes quite stable. Thus, the distance (range width) between the upper limit curve and the lower limit curve illustrated in FIG. 5 is not necessarily constant at every time point. Specifically, FIG. 5 demonstrates that in time intervals with a steep curve slope, the range width is significantly larger, whereas in time intervals with a gentle curve slope, the range width is noticeably smaller. This reflects that the battery quality detection method of this embodiment actively adjusts the range of the standard detection range based on different charging modes.

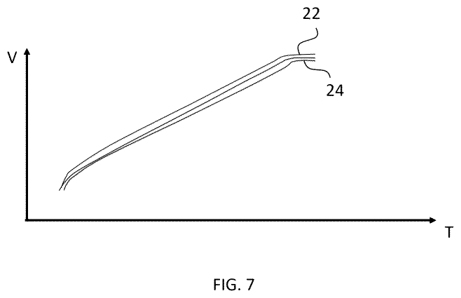

The above embodiment illustrates a method for obtaining the standard detection range via an image processing procedure, but the present invention is not limited thereto. Please refer to FIGS. 4, 6, and 7 together, where FIG. 6 is a schematic diagram illustrating a standard curve according to an embodiment of the present invention, and FIG. 7 is a schematic diagram illustrating a standard curve, an upper limit curve, and a lower limit curve according to an embodiment of the present invention. As shown, after selecting a plurality of test data with a data concentration greater than a first threshold, the filtered test data can be processed to obtain a standard curve 20. In practice, the standard curve 20 may be a curve plotted based on the average value of the filtered test data (average curve) or based on the median value of the filtered test data (median value curve). As long as the standard curve 20 is associated with the filtered test data, this embodiment does not restrict the method of processing the filtered test data to derive the standard curve 20.

After obtaining the standard curve 20, this embodiment may further derive the upper limit curve 22 and the lower limit curve 24 from the standard curve 20. In one example, the separation/distance between the upper limit curve 22 and the standard curve 20, as well as between the lower limit curve 24 and the standard curve 20, can be calculated. For instance, the standard deviation of the filtered test data for each time interval can be computed first. Then, using the standard deviation as a parameter, the upper limit curve 22 and the lower limit curve 24 can be plotted based on the standard curve 20. For example, within a given time interval, the upper limit curve 22 might be the standard curve 20 plus two standard deviations, while the lower limit curve 24 might be the standard curve 20 minus two standard deviations. This approach, incorporating the standard deviation, allows the upper limit curve 22 and the lower limit curve 24 to reflect the characteristic that the range width is larger in time intervals with steep curve slopes and smaller in time intervals with gentle curve slopes.

It is worth mentioning that the above describes the upper limit curve 22 and the lower limit curve 24 within a single time interval, and such time intervals can be distinguished based on duration or charging mode—e.g., divided into units of minutes or hours, segmented by constant current or constant voltage charging modes, or differentiated by the magnitude of charging current (each corresponding to a distinct time interval). This embodiment imposes no restrictions in this regard. Additionally, obtaining the standard curve, upper limit curve, and the lower limit curve does not necessarily require an image processing procedure. For example, this embodiment may use a computer to directly analyze the plurality of test data within each time interval, calculating the average or median value of the test data within each interval, as well as the standard deviation of the test data within the corresponding interval. Subsequently, the average (or median) and standard deviation are processed to obtain the values of the upper limit curve and the lower limit curve for the corresponding time interval.

In one example, if the average value and standard deviation for a time interval are calculated, adding one or two standard deviations to the average yields the value of the upper limit curve for that interval. Similarly, subtracting one or two standard deviations from the average yields the value of the lower limit curve for that interval. Those skilled in the art will understand that linking the average (or median) values across each time interval forms the standard curve. Likewise, linking the values derived from processing the average (or median) with the standard deviation across each time interval forms the upper limit curve and the lower limit curve. Of course, this embodiment does not restrict the method of processing the average (or median) with the standard deviation, and those skilled in the art may determine this based on the properties of the test data or specification requirements related to the test.

In another example, after obtaining the standard curve 20, this embodiment may determine how to adjust the standard curve 20 using image processing based on different charging modes to derive the upper limit curve 22 and the lower limit curve 24. For instance, since the test data is quite stable after the battery is fully charged (time t) (deviation less than a second threshold), the image processing procedure may simply shift the standard curve 20 to generate the upper limit curve 22 and the lower limit curve 24. Conversely, before the battery is fully charged (time t), the test data fluctuates significantly (deviation not less than the second threshold), and the image processing procedure not only shifts the standard curve 20 but also stretches or compresses it to generate the upper limit curve 22 and lower limit curve 24, thereby widening the range width for this time interval. Finally, the upper limit curve 22 and the lower limit curve 24 processed separately for different time intervals are stitched together to form complete upper limit curve 22 and the lower limit curve 24. Consistent with the previous embodiment, the range between the upper limit curve 22 and the lower limit curve 24 constitutes the standard detection range described in this embodiment. In other words, this embodiment demonstrates that different charging modes (degrees of battery voltage change) correspond to specific methods for determining the standard detection range, with the standard detection range having a corresponding range width for each time interval.

Additionally, the standard curve may first be compared with a preset curve to verify its correctness. The preset curve may be obtained from specifications or measured from a standard component, and this embodiment imposes no restrictions in this regard. In practice, if the difference between the standard curve and the preset curve is excessive (exceeding a third threshold), the standard curve may be judged as abnormal, indicating that it cannot be used to generate the standard detection range.

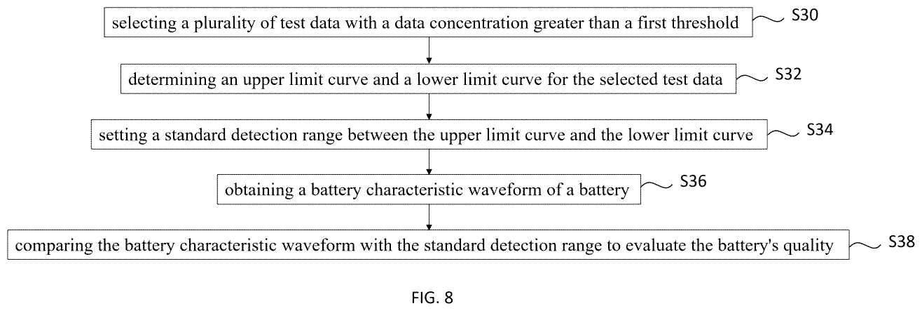

To illustrate the battery quality detection method of the present invention, please refer to FIGS. 3 through 8 together, where FIG. 8 is a flowchart illustrating the steps of a battery quality detection method according to an embodiment of the present invention. As shown, in step S30, a plurality of test data with a data concentration greater than a first threshold is selected. In step S32, an upper limit curve and a lower limit curve for the selected test data are determined. In step S34, a standard detection range is set between the upper limit curve and the lower limit curve. In step S36, a battery characteristic waveform of a battery is obtained. In step S38, the battery characteristic waveform is compared with the standard detection range to evaluate the battery's quality. Since these steps have been described in the foregoing embodiments and figures, they are not repeated here.

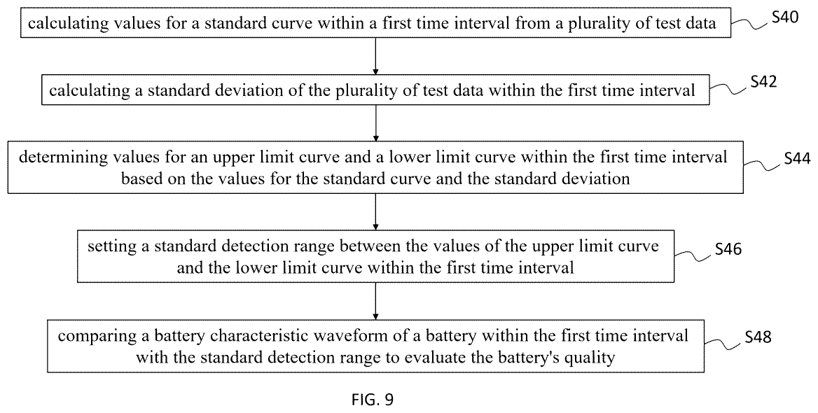

In another example, please refer to FIGS. 3 through 9 together, where FIG. 9 is a flowchart illustrating the steps of a battery quality detection method according to another embodiment of the present invention. As shown, in step S40, values for a standard curve within a first time interval are calculated from a plurality of test data. In step S42, a standard deviation of the plurality of test data within the first time interval is calculated. In step S44, values for an upper limit curve and a lower limit curve within the first time interval are determined based on the values for the standard curve and the standard deviation. In step S46, a standard detection range is set between the values of the upper limit curve and the lower limit curve within the first time interval. In step S48, a battery characteristic waveform of a battery within the first time interval is compared with the standard detection range to evaluate the battery's quality. Since these steps have been described in the foregoing embodiments and figures, they are not repeated here.

In summary, unlike traditional battery quality detection methods that are prone to misjudgments when battery voltage changes abruptly and may become overly lenient when voltage stabilizes after increasing tolerance limits, the battery quality detection method of the present invention dynamically adjusts the standard detection range using an image processing procedure. This approach maintains strict quality control when the battery voltage is stable while providing a larger standard detection range during abrupt voltage changes to reduce misjudgments, thereby enhancing the accuracy of battery quality analysis.

What is claimed is:

1. A battery quality detection method, comprising:
selecting a plurality of test data with a data concentration greater than a first threshold;
determining an upper limit curve and a lower limit curve for the selected test data;
setting a standard detection range between the upper limit curve and the lower limit curve;
obtaining a battery characteristic waveform of a battery; and
comparing the battery characteristic waveform with the standard detection range to evaluate the battery's quality.

2. The battery quality detection method according to claim 1, wherein the step of determining the upper limit curve and the lower limit curve for the selected test data, comprises:
obtaining an upper contour line and a lower contour line for the selected test data via an image processing procedure; and
generating the upper limit curve and the lower limit curve based on the upper contour line and the lower contour line, respectively.

3. The battery quality detection method according to claim 1, wherein the step of determining the upper limit curve and the lower limit curve for the selected test data, comprises:
generating a standard curve based on the selected test data; and
generating the upper limit curve and the lower limit curve via an image processing procedure based on the standard curve.

4. The battery quality detection method according to claim 3, wherein the image processing procedure at least stretches or compresses the standard curve to obtain the upper limit curve and the lower limit curve.

5. The battery quality detection method according to claim 4, wherein the step of generating the upper limit curve and the lower limit curves via the image processing procedure based on the standard curve comprises:
when a deviation of the selected test data within a time interval is less than a second threshold, shifting the standard curve within the time interval via the image processing procedure to obtain the upper limit curve and the lower limit curve within the time interval; and
when the deviation of the selected test data within the time interval is not less than the second threshold, stretching or compressing the standard curve within the time interval via the image processing procedure to obtain the upper limit curve and the lower limit curve within the time interval.

6. The battery quality detection method according to claim 3, wherein a separation between the upper limit curve and the lower limit curve forms an range width of the standard detection range, the value of the range width is at least associated with a standard deviation of the selected test data for the time interval.

7. The battery quality detection method according to claim 6, wherein the standard curve is a median value curve or an average curve of the selected test data.

8. The battery quality detection method according to claim 3, wherein when a difference between the standard curve and a preset curve deviates from a third threshold, the standard curve is judged as abnormal.

9. The battery quality detection method according to claim 1, wherein the step of comparing the battery characteristic waveform with the standard detection range to evaluate the battery's quality further comprises: using an image processing procedure to determine whether the battery characteristic waveform deviates from the standard detection range to evaluate the battery's quality.

10. A battery quality detection method, comprising:
calculating values for a standard curve within a first time interval from a plurality of test data;
calculating a standard deviation of the plurality of test data within the first time interval;
determining values for an upper limit curve and a lower limit curve within the first time interval based on the values for the standard curve and the standard deviation;
setting a standard detection range between the values of the upper limit curve and the lower limit curve within the first time interval; and
comparing a battery characteristic waveform of a battery within the first time interval with the standard detection range to evaluate the battery's quality.

11. The battery quality detection method according to claim 10, wherein the standard curve is related to an average value or a median value of the plurality of test data within the first time interval.

12. The battery quality detection method according to claim 10, wherein when the battery characteristic waveform within the first time interval deviates from the standard detection range, the battery is judged as abnormal.
